(19) United States
(12) Patent Application Publication
(10) Pub. No.: US 2022/0267890 A1
(43) Pub. Date: Aug. 25, 2022

(54) MULTIZONE CRUCIBLE APPARATUS

(71) Applicant: Dyson Technology Limited, Wiltshire (GB)

(72) Inventor: Michael Edward RENDALL, Newbury (GB)

(73) Assignee: Dyson Technology Limited, Wiltshire (GB)

(21) Appl. No.: 17/638,785

(22) PCT Filed: Aug. 21, 2020
(86) PCT No.: PCT/GB2020/052021

§ 371 Date: Feb. 25, 2022

(30) Foreign Application Priority Data
Aug. 30, 2019 (GB) 1912493.2

(51) Int. Cl. C23C 14/26; H05B 6/24; H05B 6/34; H05B 6/44; H05B 6/36; H05B 6/42; F27B 14/06; F27B 14/14; H05B 6/06; C23C 14/24; C23C 14/54

(52) U.S. Cl. CPC C23C 14/26; H05B 6/24; H05B 6/34; H05B 6/44; H05B 6/367; H05B 6/42; F27B 14/061; F27B 14/14; H05B 6/067; C23C 14/243; C23C 14/54; F27B 2014/0875

(57) ABSTRACT

A crucible apparatus includes a crucible and one or more induction coils arranged around the crucible. Upon application of electric power to the one or more induction coils, a first thermal zone is generated in at least a first portion of the crucible and a second thermal zone is generated in at least a second portion of the crucible, wherein a first thermal characteristic of the first thermal zone is different from a second thermal characteristic of the second thermal zone.

### CROSS-REFERENCE TO RELATED APPLICATIONS

This application is the National Stage of International Application No. PCT/GB2020/052021 filed Aug. 21, 2020, and claims benefit of United Kingdom Application No. 1912493.2 filed Aug. 30, 2019, each of which are herein incorporated by reference in their entirety.

### TECHNICAL FIELD

The present invention relates to methods and apparatus for induction heating of material.

### BACKGROUND

Material contained within a crucible may be heated via induction heating, whereby electric power is applied to one or more induction coils arranged around the crucible. Application of electric power induces eddy currents within the material or within a conductive material surrounding the material, which in turn heats up the material. Heating the material may cause the material to melt and vaporise. It is desirable to vaporise the material in an efficient manner.

### SUMMARY

According to a first aspect of the present invention, there is provided a crucible apparatus comprising a crucible, one or more induction coils arranged around the crucible and refractory material arranged, at least in part, around the one or more induction coils. Upon application of electric power to the one or more induction coils, a first thermal zone is generated in at least a first portion of the crucible and a second thermal zone is generated in at least a second portion of the crucible, wherein a first thermal characteristic of the first thermal zone is different from a second thermal characteristic of the second thermal zone; and wherein applying the electric power causes motion of a liquid in the crucible. Generating a first thermal zone and a second thermal zone in the crucible with different thermal characteristics may provide the ability to independently control the thermal zones in the crucible. Independently controlling the thermal zones may allow one zone, for example the second thermal zone, to be configured at a higher temperature. The crucible apparatus may, in some examples, provide a simple and efficient means for allowing a material in the crucible to be held at over 2000 degrees C., without the need for further heating systems e.g. an electron-gun system. Such a configuration may provide an efficient way of generating a high-pressure vapour flux of the material in the crucible.

The first thermal zone may be located between a base of the crucible and the second portion of the crucible. The first thermal characteristic may be a first temperature of the first thermal zone and the second thermal characteristic may be a second temperature of the second thermal zone. The second temperature may be higher than the first temperature. Configuring a lower temperature in the first thermal zone below a higher temperature in the second thermal zone may minimise spits and splashes of the material contained within the crucible. This is due to the fact that the material in the first thermal zone is heated at a lower rate than the material in the second thermal zone.

The one or more induction coils may comprise a first induction coil arranged around the first portion of the crucible and a second induction coil arranged around the second portion of the crucible. A first electric power may be applied to the first induction coil and a second electric power may be applied to the second induction coil.

The first electric power may be different from the second electric power. Application of different electric powers to the first and second induction coils allows the first and second thermal zones in the crucible to have different thermal characteristics e.g. different temperatures. Independently controlling the electric powers applied to the induction coils, and therefore independently controlling the thermal characteristics of the thermal zones, may allow for a greater control of the heating of the material in the crucible.

A first cooling system may be arranged to cool the first induction coil. Similarly, a second cooling system may be arranged to cool the second induction coil. Cooling of the induction coils may prevent over-heating and damage to the induction coils. The first cooling system and/or the second cooling system may be a water-cooling system. Use of a water-cooling system may provide a more efficient method of transferring thermal energy away from the induction coils. Having a first cooling system and a second cooling system may allow the cooling systems to be independently controlled. This provides the ability to apply different amounts of cooling to the first and second induction coils, which may themselves be at different temperatures.

Insulation may be arranged between one or more induction coils and the crucible, which may inhibit or otherwise limit the transfer of thermal energy from the crucible. Limiting the transfer of thermal energy from the crucible may protect the induction coils from the heat of the crucible. The insulation may be expanded graphite insulation. A refractory material is arranged, at least in part, around one or more induction coils. Similarly, the refractory material may limit the transfer of thermal energy from the crucible, thus protecting the induction coils from the heat of the crucible.

The crucible apparatus may be arranged such that, upon application of the electric power to the one or more inductions, heating of the crucible may be induced, thus heating the material at least partly within the crucible. Heating the material within the crucible may allow the material to be evaporated, so that the material may be deposited on a substrate.

A control system may be arranged to receive measurement data representative of a measurement of at least one of the first thermal characteristic or the second thermal characteristic, when the crucible apparatus is in use. The control system may be further arranged to control the electric power applied to the one or more induction coils based on the measurement data, when the crucible apparatus is in use. Receiving measurement data of the first and/or second thermal characteristic may provide an efficient way of controlling the electric power applied to the induction coils. The measurement data may be used as part of a feedback loop in order to maintain a first and/or second thermal characteristic automatically, without the need for manual intervention.

When the first thermal characteristic is a first temperature of the first thermal zone and the second thermal characteristic is a second temperature of the second thermal zone, a temperature sensor may be arranged to obtain the measurement data. The control system may therefore be able to control the temperature of the first and/or second thermal zones. For a material in the first thermal zone, this may provide the ability to maintain the temperature of the first thermal such that the material in the crucible is heated at a desired rate e.g. a constant rate. For a material in the second thermal zone, this may provide the ability to maintain the temperature of the second thermal zone such that the material in the crucible is evaporated at a desired rate e.g. a constant rate.

When the first thermal characteristic is a first temperature of the first thermal zone, the control system may be arranged to control the electric power applied to the one or more induction coils such that the first temperature meets or exceeds a first temperature threshold for melting of a material to be heated by the crucible apparatus, when the crucible apparatus is in use.

When the second thermal characteristic is a second temperature of the second thermal zone, the control system may be arranged to control the electric power applied to the one or more induction coils such that the second temperature meets or exceeds a second temperature threshold for evaporation of a material to be heated by the crucible apparatus, when the crucible apparatus is in use.

A chamber may be arranged between the crucible and a base of the crucible apparatus. The chamber may provide protection to the crucible apparatus should the crucible crack. The chamber may be used to collect material that escapes from the crucible, which may prevent material escaping into the deposition chamber and/or contaminating other components nearby the crucible apparatus.

A third cooling system may be arranged to cool the chamber. The third cooling system may prevent or otherwise limit the transfer of thermal energy to the base of the crucible apparatus.

The crucible apparatus may be arranged for use in an evaporative deposition process. The crucible apparatus may provide an efficient way to deposit material on a substrate. High temperatures in order to heat, evaporate and deposit the material may be achieved. Furthermore, controlling the application of electric power to the one or more induction coils can be used to control the thermal characteristics of the first and second thermal zones, and as a result, the characteristics of the deposition of the material on the substrate. For example, the ability to independently control the characteristics of the first and second thermal zones may provide control over the thickness and/or density of deposition of the material on the substrate, the rate of deposition of the material on the substrate (e.g. the vapour flux of the material), the quality of the deposition (e.g. the uniformity of the vapour flux of the material) etc. Tuning the electric power applied to one or more induction coils may provide the possibility of creating a high-pressure vapour flux of the material for deposition on the substrate.

The crucible apparatus may be arranged for use in manufacture of an energy storage device. The manufacture of energy storage devices may involve the deposition of relatively thick layers or films instead of thin films. To deposit thick films, a deposition source which has a high degree of reproducibility and control is desirable, such as the crucible apparatus of the present invention.

In accordance with a second aspect of the present invention, there is provided a method for controlling thermal characteristics of a crucible via induction heating. The method comprises providing refractory material arranged, at least in part, around one or more induction coils and applying electric power to the one or more induction coils arranged around the crucible to generate a first thermal zone in a first portion of the crucible and a second thermal zone in a second portion of the crucible, wherein a first thermal characteristic of the first thermal zone is different from a second thermal characteristic of the second thermal zone; and wherein applying the electric power causes motion of a liquid in the crucible. Generating a first thermal zone and a second thermal zone in the crucible with different thermal characteristics may provide the ability to independently control the thermal zones in the crucible. Independently controlling the thermal zones may allow one zone, for example the second thermal zone, to be configured at a higher temperature. The crucible apparatus may, in some examples, provide a simple and efficient means for allowing a material in the crucible to be held at over 2000 degrees C., without the need for further heating systems e.g. an electron-gun system. Such a configuration may provide an efficient way of generating a high-pressure vapour flux of the material in the crucible.

The electric power applied to the one or more induction coils may be controlled by controlling either a current, a voltage and/or a frequency applied to the one or more induction coils. The electric power applied to the one or more induction coils may cause melting of a first portion of a material in the first portion of the crucible and evaporation of a second portion of the material in the second portion of the crucible. Application of the electric power may cause induction heating of a material in the crucible to generate a vapour of the material. Furthermore, the vapour may be deposited on a substrate. Application of the electric power such that the first portion of material is molten and the second portion of the material is vapour may minimise spits and splashes of the material. This is due to the fact that the first portion of material is heated at a lower rate than the second portion of the material.

Controlling the electric power applied to the one or more induction coils may provide the ability to control a density of the vapour deposited on the substrate and/or a rate of depositing the vapour on the substrate.

Application of the electric power causes motion in the liquid of the crucible. Motion in the liquid of the crucible may generate stirring of the liquid, thus providing a more uniform distribution of the thermal energy and ensure that there are no or fewer hot-spots or cold-spots in the material in the crucible e.g. there is a relatively homogenous distribution of the thermal energy.

Further features will become apparent from the following description, given by way of example only, which is made with reference to the accompanying drawings.

### BRIEF DESCRIPTION OF THE DRAWINGS

FIG. 1 is a schematic diagram of a crucible apparatus according to examples;

FIG. 2 is a schematic diagram of a generating a first thermal zone and a second thermal zone in a crucible apparatus according to further examples;

FIG. 3 is a schematic diagram of measuring thermal characteristics of a first thermal zone and a second thermal zone in a crucible apparatus according to further examples;

FIG. 4 is a schematic diagram of a crucible apparatus according to further examples;

FIG. 5 is a flow diagram illustrating a method for controlling thermal characteristics of a crucible via induction heating.

### DETAILED DESCRIPTION

Details of methods and systems according to examples will become apparent from the following description, with reference to the Figures. In this description, for the purpose of explanation, numerous specific details of certain examples are set forth. Reference in the specification to “an example” or similar language means that a particular feature, structure, or characteristic described in connection with the example is included in at least that one example, but not necessarily in other examples. It should further be noted that certain examples are described schematically with certain features omitted and/or necessarily simplified for ease of explanation and understanding of the concepts underlying the examples.

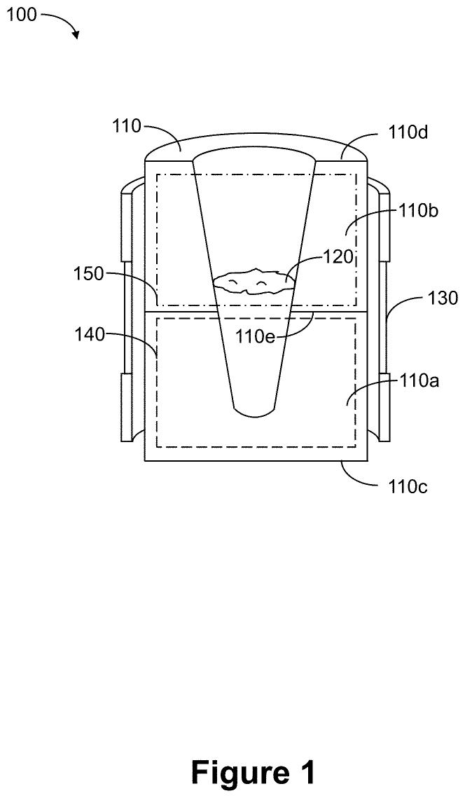

FIG. 1 is a schematic diagram of a crucible apparatus 100. The crucible apparatus 100 in this example comprises a crucible 110 and one or more induction coils 130 arranged around the crucible 110. A crucible is, for example, a vessel or container for a containing a material to be thermally heated. Material within the crucible may be heated to a temperature such that the material is melted e.g. changed into a liquid state. The crucible may be manufactured from a heat-resistant material, such as, but not limited to, graphite, porcelain, ceramic, alumina or metal. The heat-resistant material of the crucible may be chosen in order to withstand the temperature required to melt the material within the crucible. The material and dimensions (e.g. the size and/or shape) of a crucible can be chosen based on requirements of use of the crucible.

The crucible 110 may be used to heat material 120 within the crucible 110 using the one or more induction coils 130. Heating the material 120 causes a rise in temperature of the material due to an increase in thermal energy of the material 120. Heating of the material 120 may arise as a result of the application of electric power to one or more induction coils 130.

An induction coil may comprise a continuous coil of wire, which may have a plurality of turns of wire. The wire may be manufactured from or comprise an electrically conductive material, for example copper. Such a wire is therefore capable of conducting an electrical current through the induction coil. The plurality of turns of wire may be configured as successive loops or circles of wire arranged around a central axis. In some examples, the plurality of turns of wire are arranged around a central axis in circles with ever increasing radii. In other examples, the plurality of turns of wire are arranged around a central axis in circles with the same radius, but such that the centre of the circles lie on a straight line. A single length of wire may be considered to be one induction coil, as explained above. Electric power may be applied to the single induction coil. Two or more separate lengths of wire, which are for example electrically disconnected from each other, may be considered to be two or more single induction coils. Electric power may be applied to each induction coil independently e.g. with a first electric power applied to a first induction coil and a second electric power applied to a second induction coil. The presence of one or more induction coils 130 around the crucible 110 allows the material 120 in the crucible 110 to be heated via induction heating. By passing an alternating current (AC) through an induction coil, eddy currents may be induced within a material surrounded by the induction coil. An eddy current for example comprises one or more closed loops of electrical current that are induced within an electrical conductor due to the presence of an alternating magnetic field. A current can be passed through an induction coil to generate a magnetic field. Alternating the current passing through the induction coil will then alternate the magnetic field, which creates eddy currents.

The eddy currents generate thermal energy which heats up the material. For materials that are electrically conductive, this process heats up the material. Such electrically conductive materials may also be known as induction susceptors. For materials that have poor electrical conductivity, the crucible inside the coil may be manufactured out of or otherwise comprise an induction susceptor, such as graphite, which can then contain the poorly conductive material. Thus, the crucible may be inductively heated, and the material contained within the crucible may be conductively heated.

The crucible apparatus 100 may contain material 120 in the crucible 110 that is initially in a solid or liquid state. Upon heating the material 120 in the crucible 110 via induction heating, the material may change into a liquid state, which may be referred to as a molten state. Application of further heating may cause the molten material 120 to vaporise e.g. change into a gaseous state, also referred to as a vapour, evaporating from the molten material 120. Vaporised material may be deposited on to a substrate to create a layer of deposited material.

In order to put the systems and methods described herein into context, the use of the crucible apparatus 100 as an evaporative deposition source, for deposition of a material on a substrate, is provided, as an example. However, it should be noted that the systems and methods described herein may be used in a variety of other processes and this is merely an example. For example, the systems and methods described herein may be used to heat a material for other purposes, which may not necessarily involve vaporisation of the material or deposition of the material on a substrate.

Deposition is a process by which material is provided on a substrate. A substrate on which a material may be deposited is for example glass or polymer and may be rigid or flexible and is typically planar. By depositing a stack of layers on a substrate, energy storage devices such as solid-state cells may be produced. The stack of layers typically includes a first electrode layer, a second electrode layer, and an electrolyte layer between the first electrode layer and the second electrode layer.

The first electrode layer may act as a positive current collector layer. In such examples, the first electrode layer may form a positive electrode layer (which may correspond with a cathode during discharge of a cell of the energy storage device including the stack). The first electrode layer may include a material which is suitable for storing lithium ions by virtue of stable chemical reactions, such as lithium cobalt oxide, lithium iron phosphate or alkali metal polysulphide salts.

In alternative examples, there may be a separate positive current collector layer, which may be located between the first electrode layer and the substrate. In these examples, the separate positive current collector layer may include nickel foil, but it is to be appreciated that any suitable metal could be used, such as aluminium, copper or steel, or a metalised material including metalised plastics such as aluminium on polyethylene terephthalate (PET).

The second electrode layer may act as a negative current collector layer. The second electrode layer in such cases may form a negative electrode layer (which may correspond with an anode during discharge of a cell of an energy storage device including the stack). The second electrode layer may include a lithium metal, graphite, silicon or indium tin oxide (ITO). As for the first electrode layer, in other examples, the stack may include a separate negative current collector layer, which may be on the second electrode layer, with the second electrode layer between the negative current collector layer and the substrate. In examples in which the negative current collector layer is a separate layer, the negative current collector layer may include nickel foil. It is to be appreciated, though, that any suitable metal could be used for the negative current collector layer, such as aluminium, copper or steel, or a metalised material including metalised plastics such as aluminium on polyethylene terephthalate (PET).

The first and second electrode layers are typically electrically conductive. Electric current may therefore flow through the first and second electrode layers due to the flow of ions or electrons through the first and second electrode layers.

The electrolyte layer may include any suitable material which is ionically conductive, but which is also an electric insulator, such as lithium phosphorous oxynitride (LiPON). As explained above, the electrolyte layer is for example a solid layer, and may be referred to as a fast ion conductor. A solid electrolyte layer may have structure which is intermediate between that of a liquid electrolyte, which for example lacks a regular structure and includes ions which may move freely, and that of a crystalline solid. A crystalline material for example has a regular structure, with an ordered arrangement of atoms, which may be arranged as a two-dimensional or three-dimensional lattice. Ions of a crystalline material are typically immobile and may therefore be unable to move freely throughout the material.

The stack may for example be manufactured by depositing the first electrode layer on the substrate. The electrolyte layer is subsequently deposited on the first electrode layer, and the second electrode layer is then deposited on the electrolyte layer. At least one layer of the stack may be deposited using the systems or methods described herein.

The material 120 provided in the crucible 110 can be chosen depending upon the layer to be deposited on the substrate. For example, a first material may initially be arranged or otherwise provided in the crucible 110. The first material may be an electrically conductive material such as lithium cobalt oxide, for example to deposited on a substrate to form a first electrode layer for an energy storage device. Upon deposition of the first material on the substrate to the desired thickness, the first material in the crucible 110 may be replaced with a second material. The second material may be an ionically conductive but an electrically insulating material, such as lithium phosphorous oxynitride (LiPON), for example to deposited on the first electrode layer to form an electrolyte layer for the energy storage device. Once the second material has been deposited on the substrate to the desired thickness, the second material in the crucible 110 may be replaced with a third material. The third material may also be an electrically conductive material such as lithium metal, for example to deposited on the electrolyte layer to form a second electrode layer for the energy storage device. Upon deposition of the third material on the substrate to the desired thickness, further processing may be performed on the stack of deposited layers to create the energy storage device.

Typically, the manufacture of energy storage devices such as solid-state cells, may involve the deposition of relatively thick layers or films (for example, of the order of micrometres, sometimes referred to as microns) instead of thin films (for example, of the order of nanometres). To deposit films with this thickness, a deposition source which has a high degree of reproducibility and control is desirable.

Referring back to the crucible apparatus 100 of FIG. 1, in this example, the crucible 110 comprises a first portion 110a and a second portion 110b. Upon application of electric power to the one or more induction coils 130, a first thermal zone 140 is generated in at least the first portion 110a of the crucible 110 and a second thermal zone 150 is generated in at least the second portion 110b of the crucible 110. The first thermal zone 140 may have a first thermal characteristic and the second thermal zone 150 may have a second thermal characteristic, such that the first thermal characteristic is different from the second thermal characteristic.

In some examples, the thermal characteristic of the first and second thermal zones 140, 150 may be the temperature of the first and second thermal zones 140, 150. In other words, upon application of electric power to the one or more induction coils 130, the first thermal zone 140 may have a different temperature than the temperature of the second thermal zone 150. In other examples, the thermal characteristics of the first and second thermal zones 140, 150 may be different thermal characteristics than temperature, such as at least one of the thermal conductivity, the thermal resistivity or the temperature gradients of the first and second thermal zones 140, 150.

Although the first thermal zone 140 is shown as separate and distinct from the second thermal zone 150 in FIG. 1, it is to be understood that upon application of the electric power to the one or more induction coils 130 the first and second thermal zones 140, 150 in the crucible 110 may not be separate and distinct. The first and second thermal zones 140, 150 may not be limited to the areas illustrated by the dashed lines of FIG. 1.

Instead, the first and second thermal zones 140, 150 may be thought of as portions of the crucible 110 which have, on average, a given thermal characteristic. For example, on average within the first thermal zone 140, the first thermal zone 140 may have a first temperature. Similarly, on average within the second thermal zone 150, the second thermal zone 150 may have a second temperature. The first temperature and the second temperature may or may not be the same. When the first temperature and the second temperature are the same, the first and second thermal zones 140, 150 may nevertheless have different thermal characteristics due to, for example, different thermal gradients, temperature distributions or temperature profiles.

In some examples, a thermal zone may be present in a portion of the crucible. The thermal zone may be considered to be present within the material of the portion of the crucible, such that the thermal zone is limited to where the crucible material is present. In other words, the thermal zone may not extend outside the crucible material. For example, a first thermal zone 140 may be considered to be limited to the material of the portion 110a of the crucible 110. In other examples, a thermal zone may be present in a portion of the crucible and may also extend outside the crucible material. The thermal zone may be considered to be present within the material of the portion of the crucible and within a portion of a cavity of the crucible. In other words, the thermal zone may extend outside the crucible material to encompass the cavity of the crucible which contains the material 120 to be heated.

The first thermal zone 140, corresponding to the first portion 110a of the crucible 110, may be located between a base 110c of the crucible 110 and the second portion 110b of the crucible 110. The base 110c of the crucible 110 may be referred to as the bottom of the crucible 110. The first thermal zone 140 may be considered to be located in the bottom portion of the crucible 110. The second thermal zone 150, corresponding to the second portion 110b of the crucible 110, may be located between the first portion 110a of the crucible 110 and a top 110d of the crucible 110. The second thermal zone 150 may be considered to be located in the top portion of the crucible 100.

In some examples, the first portion 110a of the crucible 110 and the second portion 110b of the crucible 110 may comprise a portion of the crucible 110 that is common to both the first portion 110a and the second portion 110b. As such, the first thermal zone 140 and the second thermal zone 150 may contain a portion of the crucible 110 that is common to both the first thermal zone 140 and the second thermal zone 150.

In other words, the first thermal zone 140 and the second thermal 150 may partially overlap within the crucible 110.

In some examples, the first and second portions 110a, 110b of the crucible 110 may have different physical characteristics that enable the generation of the first and second thermal zones 140, 150. An interface between the first portion 110a of the crucible 100 and the second portion 110b of the crucible 110 is illustrated in FIG. 1 by the interface line 110e. The first potion 110a of the crucible 110 may have different physical characteristics from the second portion 110b of the crucible, such that when passing across the interface line 110e of the crucible 110, the physical characteristics of the crucible 110 change.

In one example, the first portion 110a of the crucible 110 may have a different electrical resistivity than the second portion 110b of the crucible 110. For example, the second portion 110b may have a higher electrical resistivity than the first portion 110a. When a given electric power is applied to a single induction coil surrounding or otherwise arranged around both the first and second portions 110a, 110b of the crucible 110, the second portion 110b of the crucible 110 may heat up more than the first portion 110a of the crucible 110, due to the higher electrical resistivity of the second portion 110b. This may create a second thermal zone 150 with a higher temperature than the first thermal zone 140. As explained above, the single induction coil may be considered to be one induction coil. An induction coil may comprise a continuous coil of wire, which may have a plurality of turns of wire.

In other examples, the crucible apparatus 100 may comprise a crucible 110 with the same or similar physical characteristics throughout the crucible 110. In order to generate a first thermal zone 140 and a second thermal zone 150, two or more induction coils 130 may be used in such cases. A first induction coil may be used to generate a first thermal zone 140 and a second induction coil may be used to generate a second thermal zone 150. Upon application of a first electric power to the first induction coil and a second electric power to the second induction coil, where the first electric power is different from the second electric power, the first thermal zone may have different thermal properties from the second thermal zone. For example, by applying a higher electric power to the second induction coil than the first induction coil, a higher temperature may be generated in the second thermal zone compared to the first thermal zone.

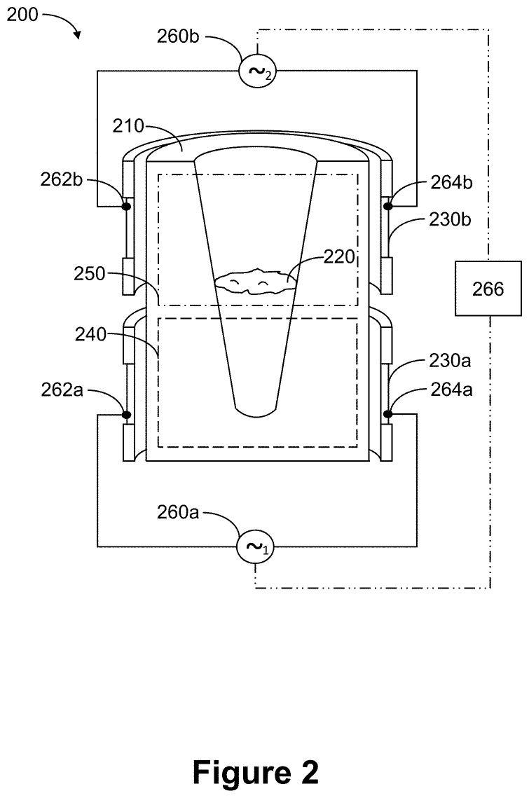

FIG. 2 is a schematic diagram of a generating a first thermal zone 240 and a second thermal zone 250 in a crucible apparatus 200. The features of FIG. 2 which are similar to corresponding features of FIG. 1 are labelled with the same reference numeral but incremented by 100. Corresponding descriptions are to be taken to apply, unless otherwise stated.

The crucible apparatus 200 comprises a first induction coil 230a and a second induction coil 230b. A first electric power source 260a may be configured to generate a first electric power, for example an AC power. The first electric power may be applied to the first induction coil 230a via one or more electric connections 262a, 264a. Arrangement of the first induction coil 230a around a portion of the crucible 210 generates a first thermal zone 240 in the crucible 210. A second electric power source 260b may be configured to generate a second electric power, for example an AC power. The second electric power may be applied to the second induction coil 230b via one or more electric connections 262b, 264b. Arrangement of the second induction coil 230b around a portion of the crucible generates a second thermal zone 250 in the crucible 210.

An electric power source may also be referred to as a power supply. An electric power source is for example an electrical device or system that can supply electric power to an electrical load, in this case one or more induction coils. An electric power source typically converts electric current from the electric power source to a given voltage, current and frequency in order to power the induction coils.

An electric power source, such as the first electric power source 260a or the second electric power source 260b, may be controlled by a control system 266. The control system 266 is for example arranged to control the electric power applied to the one or more induction coils 230a, 230b. Such control may be based on input data received by the control system 266, such as measurement data (discussed further below). The control system may include a processor, which may be referred to as a controller and may be a microcontroller. The processor may be a central processing unit (CPU) for processing data and computer-readable instructions. The control system may also include storage for storing data and computer-readable instructions. The storage may include at least one of volatile memory, such as a Random Access Memory (RAM) and non-volatile memory, such as Read Only Memory (ROM), and/or other types of storage or memory. The storage may be an on-chip memory or buffer that may be accessed relatively rapidly by the processor. The storage may be communicatively coupled to the processor, e.g. by at least one bus, so that data can be transferred between the storage and the processor. In this way, computer-readable instructions for processing by the processor for controlling the crucible apparatus 210 and its various components in accordance with the examples described herein may be executed by the processor and stored in the storage. Alternatively, some or all of the computer-readable instructions may be embedded in hardware or firmware in addition to or instead of software. In some cases, the first and second induction coils 230a, 230b are arranged to receive electric power from the same power source, such as mains power, which may be referred to as a common power source. In such cases, the first and second power sources 260a, 260b may be omitted, and the control system 266 may instead receive electric power from the common power source and may control the first and second electric power supplied by the first and second induction coils 230a, 230b, respectively, to be different from one another. In yet further cases, there may be a first control system arranged to control the first electric power supplied by the first power source 260a and a second control system arranged to control the second electric power supplied by the second power source 260b such that the first electric power is different from the second electric power. In such cases, the first and/or second control system may be similar to the control system 266.

Electric power may be applied to one or more induction coils 230a, 230b by applying, for example, an AC power, e.g. using at least one power source. Control of the electric power may be provided through the control of the current, voltage and/or frequency of the AC power, for example using the control system 266. In some examples, the crucible apparatus 200 may operate at a pre-determined voltage and current. The pre-determined voltage and current may be selected to prevent the formation of plasma in the vicinity of the crucible apparatus 200 and ablation of the material 220 in the crucible 210 when the crucible apparatus 200 is surrounded by a poor or medium vacuum.

In some examples, the first electric power applied to the first induction coil 230a may be higher than the second electric power 260b applied to the second induction coil 230b. Application of a higher electric power will cause greater induction heating and a resulting higher temperature. As such, the first thermal zone 240, which corresponds to the first induction coil 230a, has a higher temperature than the second thermal zone 250 which corresponds to the second induction coil 230b in these examples.

In other examples, the second electric power applied to the second induction coil 230b may be higher than the first electric power applied to the first induction coil 230a. Application of a higher electric power will cause greater induction heating and a resulting higher temperature. As such, the second thermal zone 250, which corresponds to the second induction coil 230b, has a higher temperature than the first thermal zone 240 which corresponds to the second induction coil 230a in these examples.

When the first thermal zone 240 is at a lower temperature and the second thermal zone 250 is at a higher temperature, the material 220 contained within the crucible 210 may be melted in the first thermal zone 240 and vaporised in the second thermal zone 250. In some examples, the control system 266 may be arranged to control the electric power applied to the one or more induction coils 230a, 230b such that the first temperature meets or exceeds a first temperature threshold for melting the material 230 contained within the crucible 210. In some examples, the control system 266 may be arranged to control the electric power applied to the one or more induction coils 230a, 230b such that the second temperature meets or exceeds a second temperature threshold for evaporation of the material 230 contained within the crucible 210.

As shown in FIG. 2, the first thermal zone may contain some or a majority of the material 220 contained within the crucible 210. The second thermal zone 250 may contain some or a minority of the material 220 contained within the crucible 210. In such a scenario, a majority of the material 220 may be held at a temperature that causes the material 220 to be in a molten state and a minority of the material may be held at a temperature that causes the material 220 to be vaporised.

Configuring a lower temperature first thermal zone 240 below a higher temperature second thermal zone 250 may minimise spits and splashes of the molten material 220 in the crucible 210 as the material is heated and vaporised. This is due to the fact that the material 220 in the first thermal zone 240 is heated at a lower rate than the material 220 in the second thermal zone 250.

As mentioned above, in some examples the crucible apparatus 200 may be used as an evaporative deposition source. In such a scenario, the crucible apparatus 200 may operate at high temperatures, for example over 2000 degrees, in order to evaporate and deposit the material 220. High temperatures of over 2000 degrees may be achieved without the use of an electron-gun system to heat the material in the crucible 210. The systems and methods herein may therefore be simpler than existing systems.

In such examples, the crucible apparatus 200 may be installed within a deposition chamber. The deposition chamber may contain a substrate on which the material may be deposited. Any gas (such as air, nitrogen, argon and/or any other inert or noble gas) present in the deposition chamber may be evacuated from the deposition chamber so that the vacuum pressure in the evacuated deposition chamber reaches a pre-determined vacuum pressure. Evacuation of the deposition chamber to a pre-determined pressure may be performed with use of a vacuum pump system. Such vacuum pump systems may comprise a scroll or rotary pump and/or a turbo pump to evacuate the gas and/or air within the deposition chamber.

When the crucible apparatus 200 is used as an evaporative deposition source, controlling the application of electric power to the one or more induction coils can be used to control the thermal characteristics of the first and second thermal zones 240, 250 in the crucible. As a result, the characteristics of the first and second thermal zones 240, 250 may determine the characteristics of the deposition of the material 220 on the substrate. For example, the ability to independently control the characteristics of the first and second thermal zones 240, 250 may provide control over the thickness and/or density of deposition of the material 220 on the substrate, the rate of deposition of the material 220 on the substrate (e.g. the vapour flux of the material), the quality of the deposition (e.g. the uniformity of the vapour flux of the material) etc. Tuning the electric power applied to one or more induction coils may provide the possibility of creating a high-pressure vapour flux of the material for deposition on the substrate.

In some examples, the presence of two or more thermal zones 240, 250 may create one or more thermal gradients between the thermal zones. The creation of thermal gradients may cause motion of the molten material 220 in the crucible 210 e.g. to generate stirring of the molten material 220 in the crucible 210. The molten material 220 may be contained with a region of the first thermal zone 240 (which is generated in the first portion of the crucible 210) and a region of the second thermal zone 250 (which is generated in the second portion of the crucible 210). The regions of the first and second thermal zones 240, 250 may comprise some or all of the first and/or second thermal zones 240, 250. As such, stirring of the molten material 220 may be present between a region of the first thermal zone 240 and a region of the second thermal zone 250 due to a thermal gradient between the first thermal zone 240 and a second thermal zone 250.

Stirring of the molten material 220 may provide for a more uniform distribution of the thermal energy and thus ensure that there are no or fewer hot-spots or cold-spots in the material 220 contained in the crucible 210 when it is being heated e.g. so there is a relatively homogenous distribution of the thermal energy. Induction heating of the material 220 may also generate induction stirring of the molten material 220. Induction stirring may also provide for a more homogenous distribution of the thermal energy, and thus a more homogeneous molten material 220.

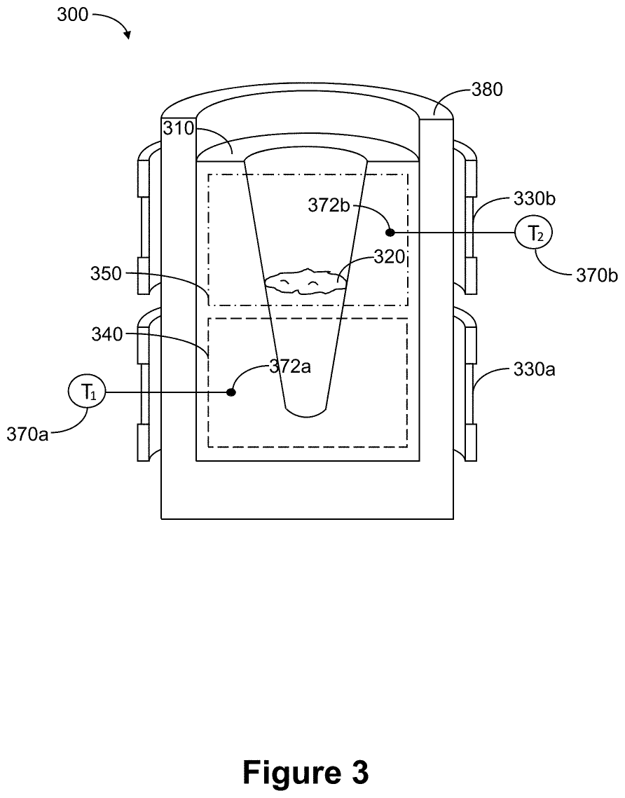

FIG. 3 is a schematic diagram of measuring thermal characteristics of a first thermal zone 340 and a second thermal zone 350 in a crucible apparatus 300. The features of FIG. 3 which are similar to corresponding features of FIG. 1 are labelled with the same reference numeral but incremented by 200. Corresponding descriptions are to be taken to apply, unless otherwise stated.

One or more temperature sensors may be coupled to the crucible 310 in order to measure thermal characteristics of the crucible 310. A first temperature sensor 370a may be coupled via a coupling mechanism 372a to the first thermal zone 340 of the crucible 310. Similarly, a second temperature sensor 370b may be coupled via a coupling mechanism 372b to the second thermal zone 350 of the crucible 310. The temperature sensors 370a, 370b may allow thermal characteristics, such as temperature, to be measured for at least one of the thermal zones 340, 350.

A coupling mechanism 372a, 372b may physically connect or couple the temperature sensor to a thermal zone 340, 350. In some examples, the temperature sensor 370a, 370b measures the temperature of the crucible itself within a given thermal zone 340, 350, as is shown in FIG. 3. For example, the temperature sensor 370a, 370b may be physically connected to the crucible itself e.g. on the outside of the crucible or within the material of the crucible. In other examples, the temperature sensor measures the temperature of the cavity of the crucible within a given thermal zone e.g. the temperature of the material contained within the crucible. For example, the temperature sensor may be physically connected to the cavity of the crucible or the material contained within the crucible.

The temperature sensors 370a, 370b may be any such device that measures the temperature of an object, such as a thermocouple, thermistor or a thermostat. The temperature sensors 370a, 370b may be arranged to be obtain measurement data representative of a measurement of at least one of a first or second thermal characteristic, respectively. In some examples, the first thermal characteristic is a first temperature of the first thermal zone and the second thermal characteristic is a second temperature of the second thermal zone.

In some examples, such as for the thermostat, measurement of the temperature or another thermal characteristic of the first and/or second thermal zone 340, 350 may be used to control or partly control the electric power applied to an induction coil. The electric power applied to an induction coil may be controlled by a control system, such as the control system 266 of FIG. 2. The control system may be arranged to control the electric power based on received input data, which may comprise the measurement data obtained by the temperature sensors 370a, 370b.

For example, the electric power applied to the first and/or second induction coil 330a, 330b may be controlled by a feedback loop that is based, at least in part, on the temperature measurements by the temperature sensors 370a, 370b for the first and/or second thermal zones 340, 350. As a result, the temperature of the first and/or second thermal zones 340, 350 can be maintained automatically, without the need for manual intervention. As such, a substantially constant vapour flux of the material 320, or a vapour flux of the material 320 with fewer vapour flux variations than existing systems, in the second thermal zone 350 may be achieved. In other words, the vaporisation of the material 320 occurs at a substantially constant rate. The vapour flux of the material may be considered to be substantially constant when the vapour flux is approximately constant. For example, the vapour flux of the material may be approximately constant within measurement tolerances or with a vapour flux variation of within plus or minus 1, 5 or 10 percent of the vapour flux.

The electric power applied to an induction coil may be controlled by a control system, such as the control system 266 in FIG. 2. For example, in response to input data indicative that a first temperature of the first thermal zone 340 is less than a first temperature threshold for melting of a material to be heated by the crucible apparatus 300, the control system may control the first electric power applied to the first induction coil 330a to increase the temperature within the first thermal zone 340 until the temperature within the first thermal zone 340 meets or exceeds the first temperature threshold Similarly, in response to input data indicative that a second temperature of the second thermal zone 350 is less than a second temperature threshold for evaporation of the material, the control system may control the second electric power applied to the second induction coil 330b to increase the temperature within the second thermal zone 350 until the temperature within the second thermal zone 350 meets or exceeds the second temperature threshold. Conversely, the control system may similarly be arranged to reduce the first and/or second electric power if it is determined that the first and/or second temperature meets or exceeds a further first and/or second temperature threshold (e.g. corresponding to a flux of material evaporated from the crucible 300 which is too high for a desired use). In some examples, insulation 380, such as expanded graphite insulation, may be arranged around the crucible 310 and between the crucible 310 and the one or more induction coils 330a, 330b. Insulation 380 is, for example, a heat-resistant material that can inhibit or otherwise limit the transfer of thermal energy. For examples, the insulation 380 may inhibit the transfer of thermal energy from the crucible 310 to the induction coils 330a, 330b. By arranging the insulation 380 between the induction coils 330a, 330b and the crucible 310, the insulation 380 may protect the induction coils 330a, 330b from the heat from the crucible 310.

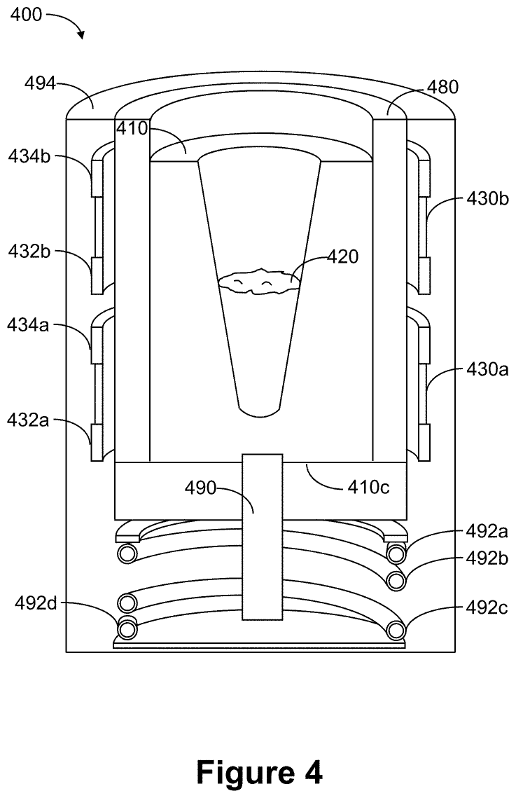

FIG. 4 is a schematic diagram of a crucible apparatus 400. The features of FIG. 4 which are similar to corresponding features of FIG. 1 are labelled with the same reference numeral but incremented by 300. Corresponding descriptions are to be taken to apply, unless otherwise stated.

The crucible apparatus 400, as explained above, may comprise a crucible 410 for containing material 420 to be heated via induction heating and one or more induction coils (in this case, a first and second induction coil 430a, 430b) that are arranged around the crucible 410. Between the crucible 410 and the first and second induction coils 430a, 430b, insulation 480 may be present in order to protect the first and second induction coils 430a, 430b from the heat generated within the crucible 410 upon application of electric power.

In some examples, at least one induction coil may be cooled by a cooling system. A first cooling system may be arranged to cool the first induction coil 430a. A second cooling system may be arranged to cool the second induction coil 430b. The first cooling system and the second cooling system may apply different amounts of cooling to the first induction coil 430a and the second induction coil 430b, respectively.

In some examples, at least one of the cooling systems is a water-cooling system. For example, at least one induction coil may be water-cooled by a water-cooling system. For example, the first induction coil 430a may be water-cooled by a first water-cooling system, which in this case includes first and second elements 432a and 434a (although this is merely an example). First and second elements 432a and 434a may comprise a tube, pipe or other such hollow container that allows water to flow through. The first and second elements 432a and 434a may be in thermal contact with the first induction coil 430a such that thermal energy may pass from the first induction coil 430a to the first and second elements 432a and 434a and to the water within. In FIG. 4, the first element 432a is extends parallel to a lower edge of the first induction coil 430a and the second element 434a extends parallel to an upper edge of the first induction coil 430a, although this is merely an example Water flowing through the first and second elements 432a and 434a, around the first induction coil 430a, may heat up due to the thermal contact with the first induction coil 430a and transfer at least some of the thermal energy from the first induction coil away. As such, the water is used as a heat-transfer medium. The first and second elements 432a and 434a may be manufactured from copper, metal or other such thermally conductive material. Transferring the thermal energy away from the first induction coil 430a will cool the first induction coil 430a. The water in the water-cooling system 432a, 434a may pass through the first element 432a and subsequently pass through the second element 434a in order to cool the first induction coil 430a.

Similarly, the second induction coil 430b may be water-cooled by a second water-cooling system, which in this example includes third and fourth elements 432b and 434b (although this is merely an example). The third and fourth elements 432b, 434b may be similar to the first and second elements 432a, 434a described above, but arranged to cool the second induction coil 430b rather than the first induction coil 430a.

The first water-cooling system 432a, 434a and the second water-cooling system 432b, 434b may be independent from each other or linked together. In one example, when the first water-cooling system 432a, 434a and the second water-cooling system 432b, 434b are independent, the water used in one water-cooling system is separate from the water used in the other system e.g. the systems run in parallel. In another example, when the first water-cooling system 432a, 434a and the second water-cooling system 432b, 434b are linked together, water is re-circulated from one water-cooling system to another e.g. the systems run in series.

Although the water-cooling system has been described in relation to using water as the heat-transfer medium, it is to be noted that other coolants may be used. For example, other liquids with a high heat capacity may be used in the water-cooling systems, such as oil, deionized water or a solution of a suitable organic chemical e.g. ethylene glycol, diethylene glycol or propylene glycol.

A chamber 490, located below the crucible 410, may be installed in order to provide protection to the crucible apparatus 400 should the crucible 410 crack. The chamber 490 may be used to collect material 420 that escapes from the crucible 410, e.g. if the crucible 410 cracks. Collecting material 420 that leaks from the crucible 410 may prevent the material 420 from escaping into a deposition chamber and/or from contaminating other components nearby the crucible apparatus 400.

In addition, the chamber 490 may be water-cooled in order to prevent the transfer of thermal energy to the base 410c of the crucible apparatus 400. A third water-cooling system 492a-492d may be present to cool the base 410c of the crucible apparatus 400. The water for the water-cooling system 492a-492d may enter the water-cooling system at a first element 492a, pass through a second element 492b, pass through a third element 492c and may exit the water-cooling system at a fourth element 492d. As explained in relation to the first water-cooling system 432a, 434a and the second water-cooling system 432b, 434b, the first, second, third and fourth elements 492a, 492b, 492c and 492d may comprise a continuous tube, pipe or other such hollow container that allows water or another coolant to flow through.

In some examples, the induction coils 430a, 430b may be encased in a refractory material 494. The refractory material 494 is arranged, at least in part, around the one or more induction coils 430a, 430b. The first water-cooling system 432a, 434a and the second water-cooling system 432b, 434b may also be housed in the refractory material 494. A refractory material 494 is, for example, a heat-resistant material that can inhibit or otherwise limit the transfer of thermal energy. For example, the refractory material 494 may inhibit the transfer of thermal energy from the crucible 310 to the induction coils 330a, 330b. By encasing the induction coils 330a, 330b in the refractory material 494, the refractory material 494 may protect the induction coils 330a, 330b from damage from the heat from the crucible 310.

In some examples, the size and/or the shape of the crucible apparatus 400 may be configured in order to match the size and/or the shape of a substrate. For example, a crucible apparatus may be manufactured or selected with particular dimensions in order to match the dimensions of the substrate. In other words, an appropriate crucible may be chosen for a given substrate. Matching the size and/or shape of the crucible apparatus 400 to the profile of the substrate may provide an efficient way to optimise the deposition of the material 420 in the crucible 410 on to the substrate. For example, the material 420 in the crucible may be deposited on all of the substrate, such that no portion of the substrate does not contain deposited material.

In some examples, the size and/or the shape of the crucible apparatus 400 may be configured in order to match a deposition chamber that contains the substrate. For example, a crucible apparatus may be manufactured or selected with particular dimensions in order to match the dimensions of the deposition chamber. In other words, an appropriate crucible may be chosen for a given deposition chamber. Matching the size and/or shape of the crucible apparatus 400 to the deposition chamber may also provide an efficient way to optimise the deposition of the material 420 in the crucible 410 on to the substrate in the deposition chamber. The crucible apparatus 400 may be selected based on a particular shape and/or dimension that matches the shape and/or dimension of the deposition chamber. Such selection may provide an efficient way to increase the size of the deposition of the material on the substrate.

In some examples, the crucible apparatus 400 is installed within a deposition chamber. Due to the first and second thermal zones of the crucible 410 providing vaporised material 420, the deposition chamber may be maintained at higher vacuum pressures (i.e. lower vacuum) than an equivalent apparatus that comprises an electron-gun system to provide vaporised material. In such a scenario, maintaining the deposition chamber at a higher pressure may reduce the time for the air or gas in the deposition chamber to be evacuated, creating a more efficient process.

Maintaining the deposition chamber at higher pressures may provide the ability to perform reactive depositions during the deposition process. In reactive depositions, a gas in the deposition chamber, which may be injected into the deposition chamber, may comprise one or more chemical elements and/or molecules that may chemically react with the vaporised material 420 from the crucible apparatus 400. As a result, the vaporised material 420 and the elements and/or molecules may chemically react, yielding one or more products. The products may then be used as part of the deposition process. For example, the products may be deposited on a substrate.

In some examples, the crucible apparatus 400 may comprise a continuously fed system, whereby material is continuously fed or is fed more frequently than otherwise into the crucible 410, so that the amount of material 420 in the crucible 410 does not decrease or remains above a certain threshold amount. Inclusion of a continuously fed system in the crucible apparatus 400 may avoid the need to switch the crucible apparatus 400 off, in order to replenish the material 420 in the crucible 410. Such a scenario may decrease the amount of down-time of the crucible apparatus and provide a more efficient system.

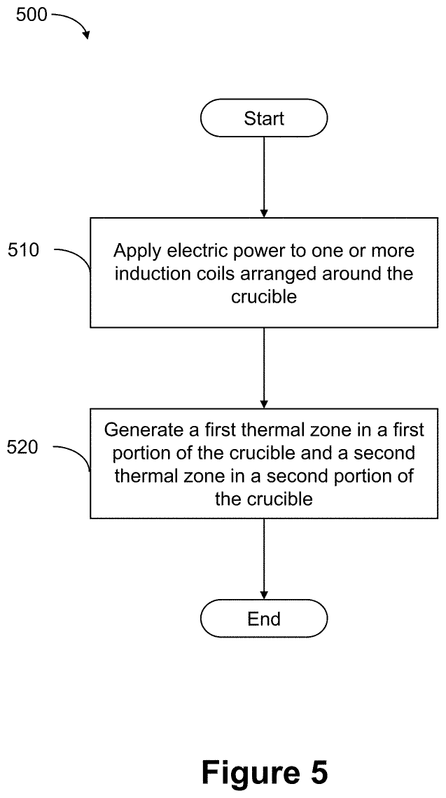

FIG. 5 is a flow diagram illustrating a method 500 for controlling thermal characteristics of a crucible via induction heating. The method may be implemented using the systems described above.

In block 510 of the flow diagram 500, electric power is applied to one or more induction coils arranged around the crucible.

In block 520 of the flow diagram 500, a first thermal zone in a first portion of the crucible is generated and a second thermal zone in a second portion of the crucible is generated, wherein a first thermal characteristic of the first thermal zone is different from a second thermal characteristic of the second thermal zone.

Such a method for example allows a material within the crucible to be heated, for example for evaporative deposition of the material on a substrate. With such a method, the first and second thermal characteristics may be controlled appropriately to control a state of the material within the crucible as desired. The material may therefore be deposited in a more stable manner than otherwise. Furthermore, with such a method, the material may be deposited more efficiently than otherwise, with fewer breaks in operation than otherwise. For example, a feedback loop may be used to control the first and second thermal characteristics appropriately, for example to provide for heating of the material as desired. In this way, the method for example allows a material to be deposited with an accurate and reproducible thickness on a substrate, with reduced complexity than otherwise.

The above examples are to be understood as illustrative examples. Further examples are envisaged.

It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the accompanying claims.

1. A crucible apparatus, comprising:
a crucible;
one or more induction coils arranged around the crucible such that, upon application of electric power to the one or more induction coils, a first thermal zone is generated in at least a first portion of the crucible and a second thermal zone is generated in at least a second portion of the crucible; and
refractory material arranged, at least in part, around the one or more induction coils,
wherein a first thermal characteristic of the first thermal zone is different from a second thermal characteristic of the second thermal zone, and
wherein in use, applying the electric power causes motion of a liquid in the crucible.

2. The crucible apparatus of claim 1, wherein:
the first thermal zone is located between a base of the crucible and the second portion of the crucible;
the first thermal characteristic is a first temperature of the first thermal zone;
the second thermal characteristic is a second temperature of the second thermal zone; and
the second temperature is higher than the first temperature.

3. The crucible apparatus of claim 1, wherein the one or more induction coils comprise:
a first induction coil arranged around the first portion of the crucible; and
a second induction coil arranged around the second portion of the crucible, such that a first electric power is applicable to the first induction coil and a second electric power, different from the first electric power, is applicable to the second induction coil.

4. The crucible apparatus of claim 3, comprising:
a first cooling system arranged to cool the first induction coil; and
a second cooling system arranged to cool the second induction coil.

5. The crucible apparatus of claim 4, wherein at least one of the first cooling system or the second cooling system is a water-cooling system.

6. The crucible apparatus of claim 1, comprising insulation arranged between the one or more induction coils and the crucible.

7. (canceled)

8. The crucible apparatus of claim 1, wherein the crucible apparatus is arranged such that, upon the application of the electric power to the one or more induction coils, heating of the crucible is induced, for heating of a material at least partly within the crucible.

9. The crucible apparatus of claim 1, comprising a control system arranged to, in use:
receive measurement data representative of a measurement of at least one of the first thermal characteristic or the second thermal characteristic; and
control the electric power applied to the one or more induction coils based on the measurement data.

10. The crucible apparatus of claim 9, comprising a temperature sensor arranged to obtain the measurement data, wherein the first thermal characteristic is a first temperature of the first thermal zone and the second thermal characteristic is a second temperature of the second thermal zone.

11. The crucible apparatus of claim 9, wherein the first thermal characteristic is a first temperature of the first thermal zone, and the control system is arranged to, in use, control the electric power applied to the one or more induction coils such that the first temperature meets or exceeds a first temperature threshold for melting of a material to be heated by the crucible apparatus, in use.

12. The crucible apparatus of claim 9, wherein the second thermal characteristic is a second temperature of the second thermal zone, and the control system is arranged to, in use, control the electric power applied to the one or more induction coils such that the second temperature meets or exceeds a second temperature threshold for evaporation of a material to be heated by the crucible apparatus, in use.

13. The crucible apparatus of claim 1, comprising a chamber arranged between the crucible and a base of the crucible apparatus.

14. The crucible apparatus of claim 13, comprising a third cooling system arranged to cool the chamber.

15. The crucible apparatus of claim 1, wherein the crucible apparatus is arranged for use in an evaporative deposition process.

16. The crucible apparatus of claim 1, wherein the crucible apparatus is arranged for use in manufacture of an energy storage device.

17. A method for controlling thermal characteristics of a crucible via induction heating, the method comprising:
providing refractory material arranged, at least in part, around one or more induction coils; and
applying electric power to the one or more induction coils arranged around the crucible to generate a first thermal zone in a first portion of the crucible and a second thermal zone in a second portion of the crucible,
wherein a first thermal characteristic of the first thermal zone is different from a second thermal characteristic of the second thermal zone, and
wherein applying the electric power causes motion of a liquid in the crucible.

18. The method of claim 17, wherein:
the first thermal zone is located between a base of the crucible and the second portion of the crucible;
the first thermal characteristic is a first temperature of a first thermal zone;
the second thermal characteristic is a second temperature of a second thermal zone; and
the second temperature is higher than the first temperature.

19. The method of claim 17, wherein applying the electric power to the one or more induction coils comprises:
applying a first electric power to a first induction coil of the one or more induction coils; and
applying a second electric power, different from the first electric power, to a second induction coil of the one or more induction coils.

20. The method of claim 17, comprising controlling at least one of a current, a voltage or a frequency applied to the one or more induction coils.

21. The method of claim 17, wherein applying the electric power causes:
melting of a first portion of a material in the first portion of the crucible; and
evaporation of a second portion of the material in the second portion of the crucible.

22. The method of claim 17, wherein applying the electric power causes induction heating of a material in the crucible to generate a vapour of the material, and the method comprises depositing the vapour on a substrate.

23. The method of claim 22, comprising controlling the electric power applied to the one or more induction coils to control at least one of: a density of the vapour deposited on the substrate or a rate of depositing the vapour on the substrate.

24. The method of claim 17, comprising:
receiving measurement data representative of a measurement of at least one of the first thermal characteristic or the second thermal characteristic; and
controlling the electric power applied to the one or more induction coils based on the measurement data.
